(19) United States
(12) Patent Application Publication
(10) Pub. No.: US 2003/0087532 A1
(43) Pub. Date: May 8, 2003

(54) Integrated process for etching and cleaning oxide surfaces during the manufacture of microelectronic devices

(76) Inventors: Biao Wu, Cupertino, CA (US); Erik David Olson, Shakopee, MN (US); Ramkumar Krishnaswamy, San Jose, CA (US); Eugene Smith, Apple Valley, MN (US)

Correspondence Address: KAGAN BINDER, PLLC, SUITE 200, MAPLE ISLAND BUILDING, 221 MAIN STREET NORTH, STILLWATER, MN, 55082, US

(21) Appl. No.: 10/001,933

(22) Filed: Nov. 1, 2001

(51) Int. Cl. H01L 21/311; H01L 21/302; H01L 21/461

(52) U.S. Cl. 438/745

(57) ABSTRACT

The present invention provides integrated systems and methods for carrying out manufacturing steps relating to etching, photoresist stripping and optionally, particle removal. More specifically, the present invention provides integrated systems and methods which may be utilized to etch oxide with subsequent removal of photoresist using BOE solutions that are desirably blended on-line. Advantageously, systems and methods embodying features of the present invention include a single process chamber so that cycle time and individual step processing time are reduced, further resulting in increased productivity of the systems and methods.

### FIELD OF THE INVENTION

The present invention relates to processes and systems for manufacturing microelectronic devices. More particularly, the present invention relates to integrated processes and systems for carrying out manufacturing steps relating to etching, photoresist stripping, and particle removal.

### BACKGROUND OF THE INVENTION

In the course of manufacturing microelectronic devices, an oxide layer formed on a semiconductor wafer substrate may be etched to form oxide features on the substrate. Such oxide features are formed, for example, in gate oxide and dual gate oxide applications. To accomplish such etching, a patterned photoresist layer is formed on the oxide layer in a manner such that certain portions of the oxide layer are exposed. These exposed portions are then etched away using a suitable oxide etchant. After the etch, the patterned photoresist is generally removed by an ashing process. Ashing tends to leave a residue that is commonly removed by an additional wet chemical treatment, e.g., utilizing a semiaqueous solvent. After ashing and residue removal, the semiconductor wafer bearing the etched oxide is cleaned.

Generally, each of the etching, stripping, and cleaning steps conventionally are carried out in a manner in which each step is carried out in a different tool. Use of a multitool process has drawbacks, however. Every tool that is used takes up valuable floorspace in a fabrication facility. It would be highly desirable to reduce the total footprint (area of the facility taken up by the tool and its associated support equipment) and/or number of tools that are used to carry out etching, stripping, and cleaning. The use of multiple tools also necessarily involves transferring in-process device precursors from tool to tool. This transfer takes time, adding to the total cycle time needed to process devices. The device precursors are also exposed to risks of damage and contamination during such transfer. Process variations may also occur if the interstation transfer time is not constant from device to device. Using a single tool to carry out all of the etching, stripping, and optionally the cleaning steps would eliminate transfer delays and risks. Valuable floorspace (e.g., in the cleanroom of a semiconductor fabrication facility) would also be used much more efficiently. Although the desire to use single tool processing is quite strong, we are not aware of any commercially viable process in which all of these steps are effectively carried out in a single tool. Thus, there remains a strong need in the art for an integrated etching, stripping, and cleaning system and process that can be implemented in a single tool.

Apart from using multiple tools to carry out the etching, stripping, and cleaning operations, conventional approaches have other drawbacks. One area of concern relates to the selection of chemistries that are to be used in each step. There are many different known etchants, many different known stripping agents, and many different cleaning approaches. Yet, there remains a demand for new chemistries that provide better performance, or equivalent performance while being more environmentally friendly, than the known chemistries.

One known etchant is an aqueous HF solution that is buffered by a salt of the HF acid. Typically, the salt most commonly used is NH₄F. This etchant may sometimes be generally referred to as the “buffered oxide solution” or “BOE solution”. The BOE solution can be purchased from commercial sources. Alternatively, U.S. Pat. No. 5,972,123 describes an approach in which ammonium hydroxide is combined with an excess of HF to form the BOE solution.

Although extremely effective in most applications, the use of such BOE solutions is not completely free of disadvantages. For example, commercially available BOE solutions are available in a limited number of premixed concentrations that may or may not be optimal for a desired application. Also, BOE solutions, once prepared, are not particularly robust to extended storage periods or fluctuations in temperature, i.e., BOE solutions tend to crystallize or otherwise destabilize under temperature or storage challenge.

It would thus be desirable to provide new chemistries to provide enhanced performance in a desirably integrated wafer treatment process or new advantages. It would further be desirable to provide new ways of utilizing known chemistries that minimize any deficiencies thereof, desirably in an integrated process.

Ozone is a known stripping agent for photoresist. However, it is believed that an integrated process in which the BOE solution is used for etching and ozone is used for stripping has not been known previously. One reason for this has been the tendency of BOE solutions to crystallize.

### SUMMARY OF THE INVENTION

The present invention provides an integrated methodology for patterned oxide etching and subsequent removal of the patterned photoresist. In preferred embodiments, etching is accomplished using on-line, blended BOE solutions (this provides fresh BOE solution to avoid the crystallization problem), and photoresist stripping is accomplished with gaseous and/or aqueous ozone. Optionally, the integrated methodology of the present invention may also incorporate a particle removal treatment (particularly suitable as a pre-implant and/or prediffusion cleaning operation) after the photoresist is removed. While any conventional particle removal treatment may be used in the integrated process, a preferred treatment involves etching with dilute, aqueous HF to remove any dirty, inadvertently grown oxide resulting from the photoresist strip and then oxidizing with ozone to regrow a clean, chemically grown oxide.

The integrated methodology of the present invention may be advantageously implemented in a commercially available spray processor system, for example, in the MERCURY or ZETA spray processor systems commercially available from FSI International, Inc., Chaska, Minn. Either of these systems is an excellent facilitator of the integrated methodology. Each system allows the etch, strip, and optional particle removal treatment to be carried out as an integrated sequence in a single process chamber, optionally using a single process recipe from batch to batch.

The integrated methodology of the present invention offers numerous advantages when carried out in a single process chamber. First, cycle time is reduced because the in-process device precursors need not be transferred from station to station to carry out any of the processing steps. Additionally, the individual process steps themselves are rapidly carried out as compared to conventional processes. This provides improved productivity through better throughput and step reduction. Elimination of station to station transfer may also help to improve device yield, because in-process device precursors tend to be subject to risks of damage, mistakes, contamination, and the like during station to station transfer. Station to station transfer and time variations resulting from station to station transfer are also completely avoided. Because process steps may occur more rapidly, less water and chemicals may be used. The integrated methodology may also provide a more consistent process signature from wafer to wafer and batch to batch.

In one aspect, the present invention relates to a method of treating an in-process microelectronic device precursor. The in-process microelectronic device precursor comprises a substrate, a first oxide layer over at least a portion of the substrate, and a patterned photoresist over the first oxide layer and exposing one or more portions of the first oxide layer. A first etchant comprising aqueous HF and a buffering amount of a fluoride salt is caused to etch one or more portions of the first oxide layer. After etching, a first oxidant is caused to strip or substantially remove the patterned photoresist and to form a second layer of oxide.

In another aspect, the present invention relates to a method of treating an in-process microelectronic device precursor. The in-process microelectronic device precursor comprises a substrate, a first oxide layer over at least a portion of the substrate, and a patterned photoresist over the first oxide layer and exposing one or more portions of the first oxide layer. A first etchant comprising aqueous HF and a buffering amount of a fluoride salt is caused to etch one or more portions of the exposed first oxide layer. After etching, a first oxidant comprising ozone is caused to strip or substantially remove the patterned photoresist and to form a second oxide layer on the portions of the substrate exposed by the etch.

In another aspect, the present invention relates to a method of treating an in-process microelectronic device precursor. The in-process microelectronic device precursor comprises a substrate, a first oxide layer over at least a portion of the substrate, and a patterned photoresist over the first oxide layer and exposing one or more portions of the first oxide layer. A first etchant is caused to etch one or more portions of the exposed first oxide layer. After etching, a first oxidant is caused to strip the patterned photoresist and to form a second layer of oxide on the portions of the substrate exposed by the etch. After stripping the photoresist, a second etchant selectively removes at least a portion of the second layer of oxide relative to the first oxide layer.

In another aspect, the present invention relates to a method of treating an in-process microelectronic device precursor. The in-process microelectronic device precursor comprises a substrate, a first oxide layer over at least a portion of the substrate, and a patterned photoresist over the first oxide layer and exposing one or more portions of the first oxide layer. A first etchant comprising aqueous HF and a buffering amount of a fluoride salt is caused to etch one or more portions of the exposed first oxide layer. After etching, a first oxidant comprising ozone is caused to strip or substantially remove the patterned photoresist and to form a second layer of oxide on the portions of the substrate exposed by the etch. After stripping the photoresist, a second etchant comprising HF is used to selectively remove at least a portion of the second oxide layer relative to the first oxide layer.

In another aspect, the present invention relates to a method of treating an in-process microelectronic device precursor. The in-process microelectronic device precursor comprises a substrate, a first oxide layer over at least a portion of the substrate, and a patterned photoresist over the first oxide layer and exposing one or more portions of the first oxide layer. A first etchant is caused to etch one or more portions of the exposed first oxide layer. After etching, a first oxidant is caused to strip or substantially remove the patterned photoresist and to form a second layer of oxide on the portions of the substrate exposed by the etch. After stripping the photoresist, a second etchant selectively removes at least a portion of the second layer of oxide relative to the oxide composition. After removing at least a portion of the second layer of oxide, a second oxidant is caused to form a third layer of oxide on the device precursor.

In another aspect, the present invention relates to a method of treating an in-process microelectronic device precursor. The in-process microelectronic device comprises a substrate, a first oxide layer over at least a portion of the substrate, and a patterned photoresist over the first oxide layer and exposing one or more portions of the first oxide layer. A first etchant comprising aqueous HF and a buffering amount of a fluoride salt is caused to etch one or more portions of the exposed first oxide layer. After etching, a first oxidant comprising ozone is caused to strip or substantially remove the patterned photoresist and to form a second oxide layer on the portions of the substrate exposed by the etch. After stripping the photoresist, a second etchant comprising HF is used to selectively remove at least a portion of the second oxide layer relative to the first oxide layer. After selectively removing at least a portion of the second oxide layer, a second oxidant comprising ozone is used to form a third oxide layer on the device precursor.

### BRIEF DESCRIPTION OF THE DRAWINGS

The above mentioned and other advantages of the present invention, and the manner of attaining them, will become more apparent and the invention itself will be better understood by reference to the following description of the embodiments of the invention taken in conjunction with the accompanying drawings, wherein:

FIG. 1 is a schematic illustration of an in-process microelectronic device precursor on which a patterned photoresist overlies an oxide layer;

FIG. 2 is a schematic flowchart of one embodiment of a processing methodology of the present invention;

FIG. 3a is a schematic illustration of the precursor of FIG. 1 in which exposed portions of the oxide layer have been etched;

FIG. 3b is a schematic illustration of the precursor of FIG. 3a in which the patterned photoresist layer has been removed, and thin films of chemically grown oxide have formed over exposed areas of the substrate;

FIG. 3c is a schematic illustration of the precursor of FIG. 3b in which the chemically grown oxide has been removed;

FIG. 3d is a schematic illustration of the precursor of FIG. 3c in which a clean, chemically grown oxide is formed on the exposed portions of the substrate;

FIG. 4 is a schematic illustration of an alternative embodiment of the device precursor of FIG. 1 in which only a portion of the exposed oxide is etched away;

FIG. 5 is a schematic flowchart of a preferred embodiment of the methodology of FIG. 2.

### DETAILED DESCRIPTION OF THE PRESENTLY PREFERRED EMBODIMENTS

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention.

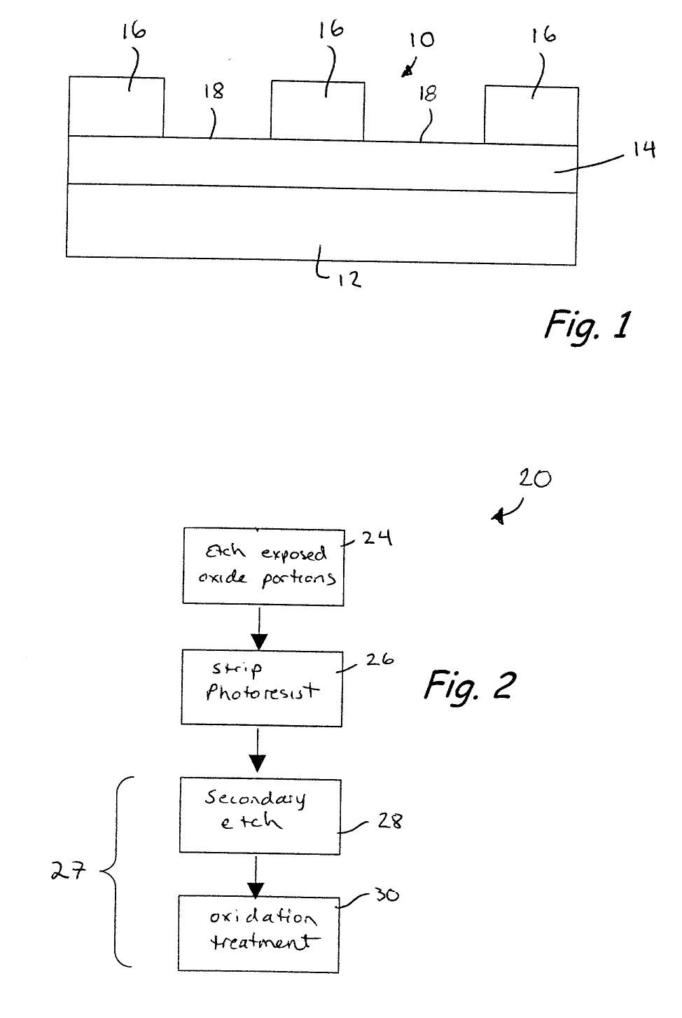

The present invention provides an integrated approach for carrying out etching, photoresist stripping, and optionally, particle cleaning that has wide applicability and may be used to form all or a portion of one or more of the many layers or structures of microelectronic devices. For purposes of illustration, the present invention now will be described with reference to the formation of a patterned oxide layer on a representative in-process microelectronic device precursor of the type shown in FIG. 1. Such an approach is useful, for instance, in forming gate oxide or dual gate oxide structures, i.e., where two or more transistors or different regions of a microelectronic device have gate oxides of different thicknesses.

In FIG. 1, in-process microelectronic device precursor 10 includes a semiconductor substrate 12 and first oxide layer 14 formed on the substrate 12. Semiconductor substrate 12 generally comprises one or more semiconductive materials such as silicon, gallium arsenide, germanium, silicon germanium, indium phosphide, combinations of these, and the like. Silicon semiconductor wafers are presently preferred for use as substrate 12. First oxide layer 14 may comprise any one or more conventional oxide materials, such as silicon dioxide, formed in accordance with conventional practices. In representative embodiments of the invention, first oxide layer 14 may comprise a thermally grown oxide (“T_{OX}”) formed on a bare semiconductor substrate by heating the substrate in an appropriate oxidizing atmosphere. Such oxides are also often referred to as “sacrificial” or “gate” oxide layers. Typically, a thermally grown oxide layer will have a thickness in the range of 50 to 10,000 angstroms. One representative thickness for a T_{OX} layer is about 300 angstroms.

Photoresist layer 16 is formed and patterned over first oxide layer 14 in a manner such that one or more portions 18 of first oxide layer 14 are exposed. The patterned photoresist layer 16 functions, at least in part, as a protective mask to allow the exposed portions of first oxide layer 14 to be selectively removed using a suitable etchant. The type of photoresist is not believed to be critical, and any suitable photoresist materials may be used.

In preferred embodiments of the invention in which an etchant comprising aqueous HF buffered with a corresponding fluoride salt such as ammonium fluoride (commonly referred to as a “buffered oxide etchant” or the “BOE” solution ) will be used to etch a T_{OX} layer, a suitable photoresist is commercially available as TOK-3450 from Tokyo Ohka Kogyo Co., Ltd. Preferably, photoresist materials compatible with the BOE solution and that may be stripped using an ozone solution are employed, as such photoresist materials facilitate an integrated process in which the BOE solution and subsequent ozone stripping are used in combination.

The thickness of patterned photoresist layer 16 may vary within a wide range and may be selected in accordance with conventional practices. Generally, layer 16 is as thin as practical for the desired process conditions. As one specific example, when using a buffered oxide etchant to etch a T_{OX} layer having a thickness in the range of 200 to 500 angstroms, patterned photoresist layer 16 may have a thickness in the range of 5,000 to 15,000 angstroms, preferably about 10,000 angstroms.

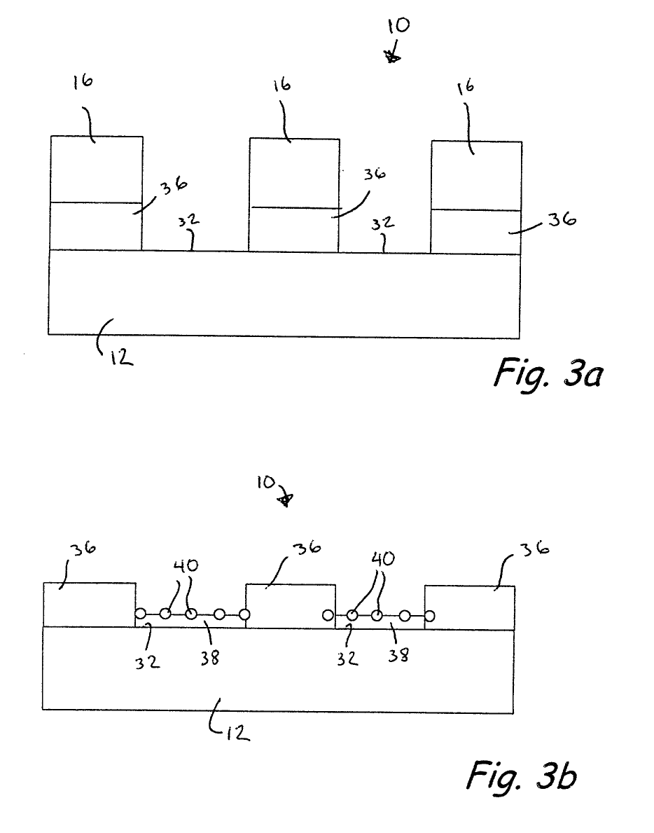

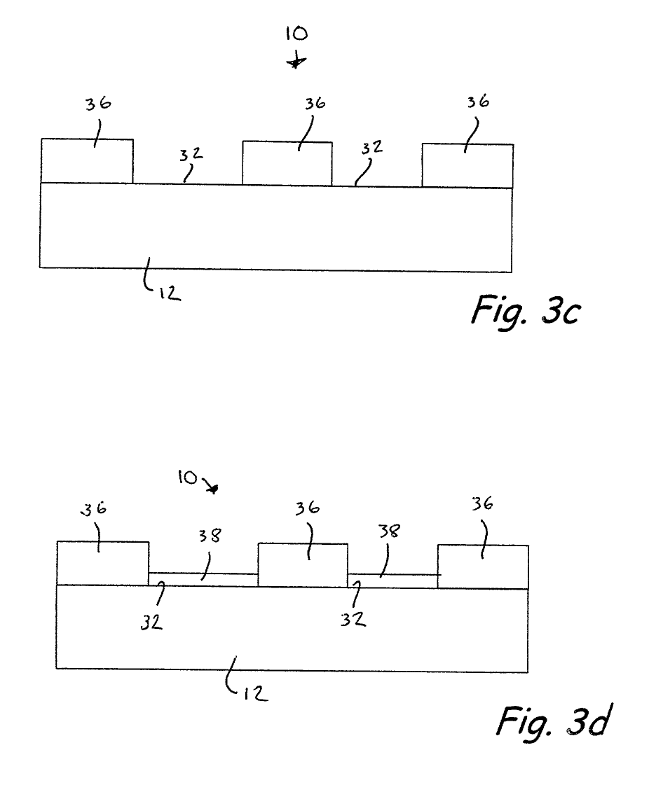

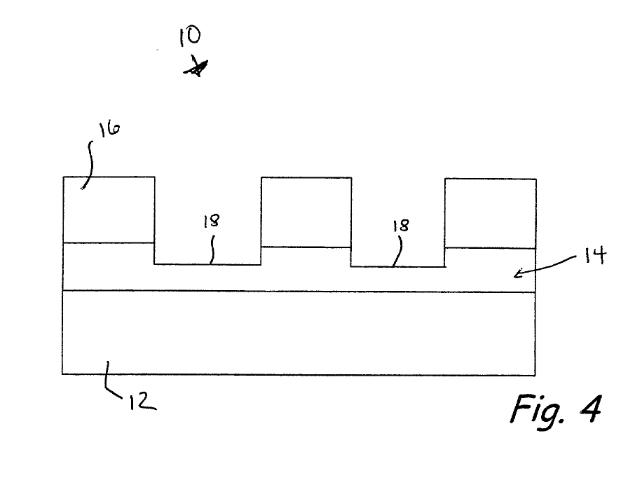

FIG. 2 is a flowchart of the process steps of one representative, integrated methodology 20 of the present invention for carrying out etching, photoresist stripping, and particle removal treatments upon device precursor 10 of FIG. 1. FIGS. 3a through 3d and FIG. 4 show how the structure of device precursor 10 is modified as each step of methodology 20 is carried out. The following discussion will explain each step of methodology 20 of FIG. 2. As each step is explained, the impact upon the structure of device precursor 10 will be explained with reference to the appropriate illustration in FIGS. 1, 3a through 3d, and 4.

Referring now to FIG. 2, an in-process microelectronic device precursor 10 of FIG. 1 is provided and in accordance with step 24 of methodology 20 is etched with a suitable first etchant or combination of etchants so that all or some of the exposed portions 18 are removed. The etchant preferably comprises an aqueous acid, more preferably comprises aqueous HF and even more preferably comprises aqueous, buffered HF. If more than one etchant is used, these may be applied to device precursor 10 simultaneously, in succession, or in overlapping fashion as desired.

FIG. 3a shows how etching step 24 selectively removes the exposed portions 18 of first oxide layer 14. For purposes of illustration, FIG. 3a shows an embodiment in which all of the exposed portions 18 have been etchingly removed, thus exposing the surface 32 of underlying semiconductor substrate 12. Of course, it is not necessary to remove all of the exposed portions 18 during this etching step. For example, FIG. 4 shows an alternative structure in which etching step 24 is carried out under conditions effective to remove only a fraction, e.g., about half of the thickness of the exposed portions 18 of first oxide layer 14. The amount of first oxide layer 14 to be removed can be determined empirically by, e.g., determining the etch rate of a given etchant under a given set of conditions and applying the etchant for that amount of time that will cause the desired amount of first oxide layer 14 to be removed. The structure of FIG. 4 has a dual height and may be advantageously used to form dual gate oxide structures.

A wide variety of etchants may be used in the practice of the present invention to carry out etching step 24. As general selection criteria, the etchant(s) to be used should not unduly attack the patterned photoresist layer 16, should uniformly etch exposed portions 18, and should etch at a suitable and/or predictable rate. Desirably, the etchant used should not unduly etch the underlying semiconductor substrate 12 in those embodiments in which etching will be carried out until substantially all of exposed portions 18 have been removed. Examples of suitable etchants include a conventional BOE solution, reactive ion etch (RIE) etchant, combinations of these, and the like.

The BOE solution is presently preferred. The BOE solution is generally an aqueous HF etchant that is buffered by a salt of HF. A preferred BOE solution comprises aqueous HF and a buffering amount of aqueous ammonium fluoride (NH₄F). The BOE solution offers many advantages. Firstly, as noted above, the BOE solution etches T_{OX} highly selectively relative to many photoresist materials due in part to the relatively mild pH of BOE solutions. Depending upon the relative amounts of HF to the ammonium fluoride, BOE solutions tend to have a pH in the range of 3 to 5. BOE solutions also etch T_{OX} selectively relative to bare silicon. The BOE solution also is characterized by very uniform etch rates allowing uniform oxide features to be formed intra-wafer and from wafer to wafer over time. As still yet another advantage, the BOE solution provides favorable surface passivation of bare silicon surfaces.

Conventional BOE solutions are commercially available from a variety of different vendors. However, such commercially available BOE solutions can have some drawbacks. First, these solutions are pre-mixed and thus may be available only in a limited number of formulations. Second, once formed, BOE solutions may have a tendency to crystallize if stored too long before use or if stored in temperatures that are too cold. Accordingly, it may be more desirable to prepare a BOE solution on demand for supply to the point of use.

Accordingly, in one preferred embodiment of the present invention, a BOE solution may be prepared by combining aqueous ammonium hydroxide with a molar excess of aqueous HF (excess with respect to the ammonium fluoride) in deionized water according to the following reaction:

NH₄OH+2HF→NH₄F+HF+H₂O+heat

This on-demand blending can be automated and allows BOE solutions to be formed with any desired ratio of HF to ammonium fluoride. The following are two representative formulations of the BOE solution that may be formed on demand when using 29 weight percent aqueous NH₄OH, 49 weight percent aqueous HF, and deionized water (all flow rates in ml/min):

| Flow rate of NH₄OH | Flow rate of HF | Flow rate of water |
|---|---|---|
| 75 | 50 | 1500 |
| 95 | 50 | 1500 |

While the above table shows embodiments of the BOE solution that are supplied at a total flow rate of 1625 ml/min and 1635 ml/min, respectively, combining the ingredients in similar relative amounts at other total flow rates ml/min, e.g., total flow rates in the range of about 500 ml/min (or less) to 3000 ml/min (or more), preferably from about 500 ml/min to about 2000 ml/min, would be suitable. The relative amounts of the HF, water, and ammonium hydroxide flows may also be varied within a wide range. For example, on a relative basis, preferred BOE solutions of the present invention may be formulated from 15 ml/min to about 300 ml/min of 29 weight percent aqueous ammonium hydroxide and from about 15 ml/min to about 300 ml/min of 49 weight percent aqueous HF per 1000 ml/min of water.

Typically, the etching step 24 is finished by rinsing the device precursor with deionized water. This rinsing could be done using hot or cold deionized water, although it is generally desirable to avoid rinsing device precursor with hot deionized water if there are any exposed silicon surfaces. When using either the MERCURY or ZETA spray processor to carry out the integrated process of the present invention, rinsing with about 4 to about 16 liters of water per minute for about 3 to 12 minutes, preferably 6 minutes would be preferred.

After the etching step, a first oxidant is caused to strip the patterned photoresist layer 16 in stripping step 26 in order to remove at least a portion of the photoresist layer 16. One or more such first oxidants maybe used. If more than one oxidant is used, they may be applied simultaneously, in succession, or in overlapping fashion.

In some embodiments of the present invention, stripping step 26 may be carried out using any conventional photoresist stripping approach in which the oxidant comprises SPM chemistry, APM chemistry, ozone gas, ozonated water, combinations of these, and/or the like. In particularly preferred embodiments, however, the first oxidant of the present invention comprises ozone. The ozone can be introduced as a gas and/or in solution, e.g., as ozonated water. The ozone, whether introduced as a gas or in a solution, may be co-introduced with one or more other fluids such as one or more separate streams, sprays, and/or the like of deionized water. If desired, all or a portion of the co-introduced deionized water may be supplied as a liquid, vapor and/or steam.

Ozonated water desirably has an ozone concentration that is relatively high in order to be used effectively for photoresist stripping. For example, the use of ozonated water containing on the order of about 1 to 500 ppm ozone, preferably at least about 50 ppm to about 120 ppm, is highly desirable. FSI International, Inc. markets its MERCURY and ZETA brand spray processors in combination with an available module that produces ozonated water with an ozone concentration up to about 120 ppm. The ozone generator is generally described in U.S. Pat. No. 5,971,368. When using the MERCURY or ZETA spray processors, using about 1 to 20, preferably about 15 liters per minute of ozonated water containing 50 ppm to 90 ppm ozone would be suitable.

Advantageously, a first oxidant comprising ozone can remove all of photoresist layer 16 and may be used as a complete replacement of the conventional ashing, SPM, and APM approaches. This significantly reduces the chemical and chemical disposal costs and provides a more environmentally friendly stripping process.

The result of stripping step 26 is shown in FIG. 3b. All of the patterned photoresist layer 16 has been removed, providing device precursor 10 with patterned T_{OX} features 36 on substrate 12. Because stripping step 26 involves applying an oxidant to substrate 12, a relatively thin, second oxide layer 38 (a “chemical grown” oxide) tends to form on the exposed substrate surface 32. The second oxide layer 38 typically is on the order of about 10 to about 12 angstroms thick.

Stripping step 26 may be completed by rinsing device precursor with deionized water. This rinse may be carried out using hot or cold deionized water. However, because the exposed surface of device precursor 10 tends to be entirely hydrophilic at this point in the integrated process, hot deionized water may be safely used and is preferred. When using either the MERCURY or ZETA spray processor, rinsing with about 4 to about 16 liters of water per minute for 3 to 12 minutes, preferably 6 minutes, would be suitable. Such rinsing can be carried out at any temperature, and desirably is carried out at a temperature of from about 10° C. to about 95° C., more desirably at a temperature range of from about 10° C. to about 60° C.

Following stripping step 26, some particles 40 may be present on device precursor 10. Chemical oxide layer 38 is particularly susceptible to such particle contamination. Accordingly, particle removal treatment step 27 preferably follows stripping step 26. A variety of different particle removal treatments may be used in the practice of the present invention. For example, any of the so-called SC-1, SC-2, and/or RCA treatments may be used if desired. One particularly effective particle removing treatment involving rinsing and then drying in the presence of an agent such as isopropyl alcohol is described in U.S. Pat. Nos. 5,634,978 and 5,772,784. Equipment that may be used to carry out the treatment of U.S. Pat. Nos. 5,634,978 and 5,772,784 is commercially available under the trade designation “YIELD UP” from SCD Mountain View, Inc., Mountain View, Calif. Another extremely effective particle removal treatment involves rinsing with an ultradilute ammonia solution in the presence of magasonic energy and drying in the presence of isopropyl alcohol. Such treatments are described in Assignee's co-pending applications Ser. No. 09/311,800 filed May 13, 1999; Ser. No. 09/411,820 filed Oct. 1, 1999; and Ser. No. 09/179,243 filed Oct. 26, 1998; and corresponding equipment that may be used to carry out such treatments is commercially available under the trade designation “YIELD UP” from SCD Mountain View, Inc., Mountain View, Calif.

A particularly preferred treatment for removing particles 40 in particle removal treatment step 27 is illustrated in the flow chart of FIG. 2. This treatment involves first subjecting device precursor 10 to a secondary etch step 28 that is followed by subjecting the precursor 10 to an oxidation treatment step 30.

In secondary etch step 28, a second etchant is caused to contact device precursor 10 in a manner such that the second etchant selectively etches second oxide layer 38, i.e., chemically grown oxide, relative to the first oxide layer, i.e., T_{OX}. This etching is carried out under conditions effective to remove at least a portion, more preferably all, of second oxide layer 38. The impact of this secondary etching step 28 upon device precursor 10 is shown in FIG. 3c. For purposes of illustration, FIG. 3c shows device precursor 10 with all of second oxide layer 38 removed.

A particularly preferred etchant for use in secondary etch step 28 is dilute, aqueous HF. In the practice of the present invention, “dilute, aqueous HF” means an aqueous solution less than 5 weight percent, preferably less than 1 weight percent, more preferably less than 0.5 weight percent HF. In preferred embodiments, dilute aqueous HF of the present invention comprises 0.01 to 3, preferably 0.1 to 1 weight percent of HF. For example, one specific embodiment of an aqueous dilute HF of the present invention was prepared by combining a 1000 ml/min of 0.5% by weight aqueous HF with a 1000 ml/min flow of deionized water.

After secondary etch step 28, it may be desirable in some embodiments of the present invention to regrow a clean chemical oxide layer on any exposed silicon surfaces 32 of substrate 12. Accordingly, as shown in oxidation treatment step 30 of FIG. 2, a second oxidant is caused to contact the device precursor 10 under conditions effective to regrow such a third oxide layer 38. A preferred second oxidant is ozone which may be introduced as a gas and/or in solution in the same manner as described above with respect to stripping step 26. The use of ozonated water in oxidation treatment step 30 is presently preferred. Advantageously, and at least in part because ozonated water has a substantially neutral pH, the resulting third oxide layer 38 is nearly devoid of metallic impurities, unlike the oxides that can be formed by application of basic-pH chemicals to a substrate surface.

In contrast to conventional etching and cleaning processes that may require the use of as many as five separate tools, the present invention provides a process that may be substantially carried out in a single tool. That is, at least etching step 24 and stripping step 26 may be carried out in the same process chamber without having to transfer device precursor 10 from one tool to another. Preferably, the particle removal treatment step 27, including secondary etch 28 and oxidation treatment 30, also occurs in the very same process chamber. Each of etching step 24, stripping step 26 and particle removal treatment step 27, for example, can be easily performed in the MERCURY or ZETA brand spray processors commercially available from FSI International, Inc. In such equipment, the entire integrated methodology is carried out in a single process chamber without having to transfer the in-process device precursors to other tooling as each step is carried out. This not only improves productivity and minimizes inter-tool contamination risks, but the very expensive floorspace of a fabrication facility is used much more efficiently.

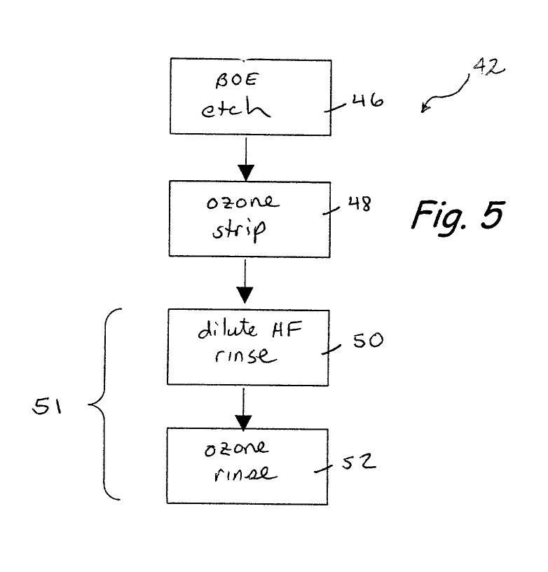

FIG. 5 is a flow chart that schematically shows a preferred embodiment 42 of methodology 20 of FIG. 2. As shown in FIG. 5, in-process microelectronic device precursor 10 is provided and etched in BOE etch step 46. Specifically, in BOE etch step 46, the exposed portions 18 of first oxide layer 14 are etched with a BOE solution (the “first etchant”) to remove some or all of the exposed oxide portions 18. In stripping step 48, patterned photoresist layer 16 is stripped with a first oxidant comprising ozone. This first oxidant also causes a second oxide layer 38 to grow on the exposed portions of substrate 12. In optional rinsing step 50, the second oxide layer 38, which tends to be contaminated with particles 40, is removed with aqueous, dilute HF. In optional rinse step 52, a clean, third oxide layer 38 is regrown to protect the substrate.

The present invention will now be further described with reference to the following examples. In these examples, a MERCURY spray processor commercially available from FSI International, Inc. was used to process the wafers. The spray processor was fitted with a commercially available module providing it with the capacity to generate ozonated water on demand. The spray processor was also fitted with components and flow control features providing it with the capacity to blend and then supply BOE solution on demand on an automated basis.

### EXAMPLE 1

### Etching Thermal Oxide (T_{OX}) with Blended BOE (NH₄OH:HF:H₂O=1.5:1:30)

Two runs of three 200 mm, oxide-coated test wafers were provided for testing. Each wafer included a blanket, T_{OX} layer having a thickness of 300 angstroms. For each of the two runs, the wafers were placed into a MERCURY spray processor in slots 1R and 25R of the right cassette and slot 13L of the left cassette. A BOE solution was blended on-line by combining 75 ml/min 29 weight percent aqueous NH₄OH , 50 ml/min 49 weight percent aqueous HF, and 1500 ml/min H₂O, for a total flow rate of 1625 ml/min. The blended BOE solution was then sprayed onto the wafers at about 24° C. to about 25° C. through the central spraypost while the wafers spun at 200 rpm. The BOE was dispensed for 3 minutes.

After the BOE dispense, the wafers were rinsed with cold, deionized water in a four step sequence according to the following recipe:

| Step | Time (sec) | RPM | Outputs |
|---|---|---|---|
| 1 | 20 | 500 | Cold line rinse, cold wafer rinse |
| 2 | 5 | 60 | Line purge, cold wafer rinse, cold side bowl |
| | | | rinse |
| 3 | 25 | 60 | Cold line rinse, cold wafer and side bowl rinse |
| 4 | 15 | 20 | Line purge, cold wafer rinse |

After the rinse was completed the wafers were dried, and the following data was obtained, wherein % uniformity was calculated using the formula standard deviation/(mean×100).

| | | thickness of | Etch rate, | |
|---|---|---|---|---|
| | | T_{OX} etched, | angstroms per | % |
| Wafer | Slot | angstroms | minute | uniformity |
| Sample 1 | 1-1R | 217.09 | 72.36 | 1.23 |
| Sample 2 | 1-25R | 221.70 | 73.90 | 1.67 |
| Sample 3 | 1-13L | 220.18 | 73.39 | 1.58 |
| Sample 4 | 2-1R | 219.25 | 73.08 | 1.49 |
| Sample 5 | 2-25R | 219.55 | 73.18 | 1.92 |
| Sample 6 | 2-13L | 218.44 | 72.81 | 1.89 |

### EXAMPLE 2

### Etching Thermal Oxide (T_{OX}) with Blended BOE (NH₄OH:HF:H₂O=1.7:1:30)

Two runs of three 200 mm, oxide-coated test wafers were provided for testing. Each wafer included a blanket, T_{OX} layer having a thickness of 6000 angstroms. For each of the two runs, the wafers were placed into a MERCURY spray processor in slots 1R and 25R of the right cassette and slot 13L of the left cassette. A BOE solution was blended on-line by combining 80 ml/min 29 weight percent aqueous NH₄OH, 50 ml/min 49 weight percent aqueous HF, and 1500 ml/min H₂O, for a total flow rate of 1630 ml/min. The blended BOE solution was then sprayed onto the wafers at about 25 to about 26° C. through the central spraypost while the wafers spun at 200 rpm. The BOE solution was dispensed for 5 minutes.

After the BOE dispense, the wafers were rinsed with cold, deionized water in a four step sequence according to the following recipe:

| Step | Time (sec) | RPM | Outputs |
|---|---|---|---|
| 1 | 20 | 500 | Cold line rinse, cold wafer rinse |
| 2 | 5 | 60 | Line purge, cold wafer rinse, cold side bowl |
| | | | rinse |
| 3 | 25 | 60 | Cold line rinse, cold wafer and side bowl rinse |
| 4 | 15 | 20 | Line purge, cold wafer rinse |

The following data was obtained:

| | | thickness of | Etch rate, | |
|---|---|---|---|---|
| | | T_{OX} etched, | angstroms per | % |
| Wafer ID | Slot | angstroms | minute | uniformity |
| Sample 7 | 1-1R | 238.06 | 47.61 | 1.86 |
| (FSI-6000-1) | | | | |
| Sample 8 | 1-25R | 236.00 | 47.20 | 2.71 |
| (FSI-6000-2) | | | | |
| Sample 9 | 1-13L | 233.72 | 46.74 | 3.27 |
| (FSI-6000-3) | | | | |
| Sample 10 | 2-1R | 233.11 | 46.62 | 3.39 |
| (FSI-6000-4) | | | | |
| Sample 11 | 2-25R | 232.62 | 46.52 | 3.13 |
| (FSI-6000-5) | | | | |
| Sample 12 | 2-13L | 239.07 | 47.81 | 0.72 |
| (FSI-6000-6) | | | | |

The data in Examples 1 and 2 shows that changing the formulation of the BOE solution results in different etch rates. Thus, the etch rate can be controlled by selecting a corresponding BOE formulation. Both BOE formulations provided excellent etch uniformity.

### EXAMPLE 3

### Etching Thermal Oxide (T_{OX}) to Expose Underlying Silicon with Blended BOE (NH₄OH:HF:H₂O=1.5:1:30) when a Patterned Photoresist Overlays at Least a Portion of the Thermal Oxide

Two 200 mm, oxide-coated test wafers (Samples 13 and 14) were provided in which the T_{OX} layer was 400 angstroms thick. Additionally, one 200 mm, oxide coated test wafer (Sample 15) was also provided in which the T_{OX} layer was 100 angstroms thick. Each test wafer also included a 1.1 micrometer thick, i-line, patterned photoresist layer overlying the T_{OX} layer such that portions of the T_{OX} layer were exposed.

For each run, the wafers were placed into a MERCURY spray processor in slots 1R and 25R of the right cassette and slot 13L of the left cassette. A BOE solution was blended on-line by combining 75 ml/min 29 weight percent aqueous NH₄OH, 50 ml/min 49 weight percent aqueous HF, and 1500 ml/min H₂O, for a total flow rate of 1625 ml/min. The blended BOE solution was then sprayed onto the wafers at about 24 to about 25° C. through the central spraypost while the wafers spun at 200 rpm. The BOE solution was dispensed for 5 minutes.

In all instances, the blended BOE completely removed the T_{OX} not covered by the photoresist to expose the underlying silicon substrate surface. No photoresist lifting was observed for any of the samples. This Example thus illustrates that an integrated BOE process in accordance with the present invention can selectively etch oxide while not substantially undercutting exposed photoresist.

### EXAMPLE 4

### BOE Etching of T_{OX} and Ozone Photoresist Stripping

One 200 mm, oxide-coated test wafer was provided in which the T_{OX} layer was 400 angstroms thick. The test wafer also included a 1.1 micrometer thick, i-line, patterned photoresist layer overlying the T_{OX} layer such that portions of the T_{OX} layer were exposed.

The wafer, as well as two bare silicon particle monitors, were placed into a MERCURY spray processor. A BOE solution was blended on-line by combining 75 ml/min 29 weight percent aqueous NH₄OH, 50 ml/min 49 weight percent aqueous HF, and 1500 ml/min H₂O, for a total flow rate of 1625 ml/min. The blended BOE solution was then sprayed onto the wafers at about 25 to about 26° C. through the central spraypost while the wafers spun at 200 rpm. The BOE was dispensed for 6.5 minutes.

After the BOE dispense, the wafers were rinsed with cold, deionized water in a four step sequence according to the following recipe:

| Step | Time (sec) | RPM | Outputs |
|---|---|---|---|
| 1 | 20 | 500 | Cold line rinse, cold wafer rinse |
| 2 | 5 | 60 | Line purge, cold wafer rinse, cold side bowl |
| | | | rinse |
| 3 | 25 | 60 | Cold line rinse, cold wafer and side bowl rinse |
| 4 | 15 | 20 | Line purge, cold wafer rinse |

After the rinse, the patterned photoresist was removed. To accomplish this, cold, ozonated water at about 20° C. and containing 60 ppm ozone was dispensed onto the wafers at 15 liters/min while the wafers spun at 500 rpm. This occurred for about 1 minute to oxidize any exposed, bare silicon. After one minute, the cold, ozonated water was co-dispensed with 8 liters/min of 95° C. hot deionized water for an additional 29 minutes. The wafers were then rinsed with first hot and then cold water, according to the following protocol. This rinsing was repeated three times.

| Step | Time (sec) | RPM | Outputs |
|---|---|---|---|
| 1 | 20 | 500 | Hot line rinse, cold wafer rinse, no side bowl |
| 2 | 5 | 60 | Line purge with N₂, cold wafer rinse, hot side |
| | | | bowl rinse |
| 3 | 25 | 60 | Hot line rinse, cold wafer and side bowl rinse |
| 4 | 15 | 20 | Line purge, Hot wafer rinse |

The hot water was supplied at about 2 to 3 liters per minute and 95° C., while the cold water was supplied at 8 liters per minute at about 20° C. Following the hot and cold water rinse, the wafers were rinsed with cold water according to the four step sequence of Example 1.

After this treatment, a chemically grown oxide having a thickness of about 11.5 to about 12 angstroms had formed on the exposed areas of the silicon. Particle analysis showed that there were about 400 particles of a size greater than 120 nanometers on the wafer. Particle data for the sample is shown in the following table:

| Number of particles | Number of | |
|---|---|---|
| >120 nm before | particles >120 nm | Particles added |
| treatment | after treatment | during treatment |
| 127 | 522 | 395 |

This Example shows that the formation of the second oxide layer, i.e., the chemically grown oxide, that can result from the photoresist strip step can contain an undesirable amount of particles.

### EXAMPLE 5

### BOE Etching, Ozone Photoresist Stripping, dHF Etch, Ozone Treatment

The process of Example 4 was carried out for another test wafer, except that after the last rinse sequence, a particle treatment removal step in accordance with that described hereinabove was carried out.

Briefly, one 200 mm, oxide-coated test wafer was provided in which the T_{OX} layer was 400 angstroms thick. The test wafer also included a 1.1 micrometer thick, i-line, patterned photoresist layer overlying the T_{OX} layer such that portions of the T_{OX} layer were exposed.

The wafer was placed into a MERCURY spray processor in slot 13 of the R cassette. A bare silicon particle monitor was also provided in the spray processor. A BOE solution was blended on-line by combining 75 ml/min 29 weight percent aqueous NH₄OH, 50 ml/min 49 weight percent aqueous HF, and 1500 ml/min H₂O, for a total flow rate of 1625 ml/min. The blended BOE solution was then sprayed onto the wafer at about 25 to about 26° C. through the central spraypost while the wafers spun at 200 rpm. The BOE was dispensed for 6.5 minutes.

After the BOE dispense, the wafer was rinsed with cold, deionized water in a four step sequence as follows:

| Step | Time (sec) | RPM | Outputs |
|---|---|---|---|
| 1 | 20 | 500 | Cold line rinse, cold wafer rinse |
| 2 | 5 | 60 | Line purge, cold wafer rinse, cold side bowl |
| | | | rinse |
| 3 | 25 | 60 | Cold line rinse, cold wafer and side bowl rinse |
| 4 | 15 | 20 | Line purge, cold wafer rinse |

After the rinse, the patterned photoresist was removed. To accomplish this, cold, ozonated water at about 20° C. and containing 50 ppm ozone was dispensed onto the wafer at 15 liters/min while the wafer spun at 500 rpm. This occurred for about 1 minute to oxidize any exposed, bare silicon. After one minute, the cold, ozonated water was co-dispensed with 8 liters/min of 95° C. hot deionized water for an additional 29 minutes. The wafer was then rinsed with first hot and then cold water, according to the following protocol. This rinsing was repeated three times.

| Step | Time (sec) | RPM | Outputs |
|---|---|---|---|
| 1 | 20 | 500 | Hot line rinse, cold wafer rinse, no side bowl |
| 2 | 5 | 60 | Line purge with N₂, cold wafer rinse, hot side |
| | | | bowl rinse |
| 3 | 25 | 60 | Hot line rinse, cold wafer and side bowl rinse |
| 4 | 15 | 20 | Line purge, Hot wafer rinse |

The hot water was supplied at about 2 to 3 liters per minute and 95° C., while the cold water was supplied at 8 liters per minute at about 20° C. Following the hot and cold water rinse, the wafer was rinsed with cold water according to the four step sequence of Example 1. After this treatment, a chemically grown oxide having a thickness of about 7 to about 10 angstroms had formed on the exposed areas of the silicon. Particle analysis showed that there were about 200 particles with at least one dimension greater than 120 nanometers on the wafer.

Particle Removal Treatment Protocol

Secondary Etch

A 200:1 aqueous, dilute HF solution (dHF) was formed by blending 1000 ml/min of 100:1 (on weight basis) aqueous HF with 1000 ml/min of deionized water. This was dispensed onto the wafer for 2 minutes at about 22° C. while the wafer spun at 200 rpm. The etch rate was about 11.5 angstroms per minute. All of the second oxide layer was removed by this step, as well as about 23 angstroms of the T_{OX} layer. After the dHF treatment, the wafer was rinsed according to the following protocol:

| Step | Time (sec) | RPM | Outputs |
|---|---|---|---|
| 1 | 20 | 500 | Cold line rinse, cold wafer rinse |
| 2 | 5 | 60 | Line purge, cold wafer rinse, cold side bowl |
| | | | rinse |
| 3 | 25 | 60 | Cold line rinse, cold wafer and side bowl rinse |
| 4 | 15 | 20 | Line purge, cold wafer rinse |

Oxidation Treatment

After the rinse, cold, ozonated water at about 20° C. and containing 50 ppm ozone was dispensed onto the wafer for 3 minutes at 15 liters/min while the wafers spun at 500 rpm. After three minutes, the cold, ozonated water was co-dispensed with 8 liters/min of 95° C. hot deionized water for an additional 29 minutes. Following the ozonated water treatment, the standard ramp/soak sequence and dry methodology of the MERCURY tool was used to complete the process.

Results

Particle performance improved dramatically in connection with this test wafer, having undergone the particle treatment removal step, as compared the test wafer of Example 4. In particular, the number of post-treatment particles with at least one dimension greater than 120 nanometers was less than the number of pretreatment particles with at least one dimension greater than 120 nanometers. The results are included in the following data along with the data from the test wafer of Example 4 for comparison:

| | | Number of | Number of | |
|---|---|---|---|---|
| | | particles | particles | Particles |
| Process | | >12 um before | >12 um after | added during |
| description | Wafer ID | treatment | treatment | treatment |
| BOE-Ozone | Test wafer- | 127 | 522 | 395 |
| | Ex. 4 | | | |
| BOE-Ozone- | Test wafer- | 180 | 160 | −23 |
| DHF-Ozone | Ex. 5 | | | |

This example thus illustrates that the integrated process of the present invention can selectively etch oxide, while not undercutting photoresist, and that, when used in combination with a particle treatment protocol in accordance with the present invention, can remove any undesired chemically grown oxide formed during the etch step.

Other embodiments of this invention will be apparent to those skilled in the art upon consideration of this specification or from practice of the invention disclosed herein. Various omissions, modifications, and changes to the principles and embodiments described herein may be made by one skilled in the art without departing from the true scope and spirit of the invention which is indicated by the following claims.

What is claimed is:

1. A method of treating an in-process microelectronic device precursor, wherein the precursor comprises a substrate, a first oxide layer over at least a portion of the substrate and a patterned photoresist over the first oxide layer and exposing one or more portions of the first oxide layer, comprising the steps of:
(a) causing a first etchant comprising aqueous HF and a buffering amount of a fluoride salt to etch one or more of the exposed portions of the first oxide layer to expose one or more portions of the substrate; and
(b) causing a first oxidant comprising ozone to strip at least a portion of the patterned photoresist, and to form a second oxide layer on the portions of the substrate exposed by the etching step.

2. The method of claim 1, wherein the fluoride salt comprises ammonium fluoride.

3. The method of claim 1, wherein at least substantially all of the exposed portions of the first oxide layer are removed.

4. The method of claim 1, further comprising the step of providing a first etchant, prior to step (a), wherein the first etchant is provided by blending on-line ingredients comprising aqueous ammonium hydroxide and a molar excess of hydrofluoric acid in deionized water.

5. The method of claim 4, wherein the ammonium hydroxide is 29 weight percent aqueous ammonium hydroxide.

6. The method of claim 5, wherein the hydrofluoric acid is 49 weight percent aqueous hydrofluoric acid.

7. The method of claim 6, wherein the ammonium hydroxide is provided at a flow rate of from about 15 ml/min to about 300 ml/min, the hydrofluoric acid is provided at a flow rate of from about 15 ml/min to about 300 ml/min and the deionized water is provided at a flow rate of from about 500 ml/min to about 3000 ml/min.

8. The method of claim 1, further comprising a rinse step prior to step (b).

9. The method of claim 1, wherein the oxidant comprises ozone gas co-introduced with deionized water.

10. The method of claim 1, wherein the oxidant comprises ozonated water.

11. The method of claim 10, wherein the ozonated water comprises from about 1 ppm to about 500 ppm ozone.

12. The method of claim 11, wherein the ozonated water comprises from about 50 ppm to about 120 ppm ozone.

13. The method of claim 1, wherein the oxidant strips substantially all of the patterned photoresist.

14. A method of treating an in-process microelectronic device precursor, wherein the precursor comprises a substrate, a first oxide layer over at least a portion of the substrate and a patterned photoresist over the first oxide layer and exposing one or more portions of the first oxide layer, comprising the steps of
a. causing a first etchant to etch one or more of the exposed portions of the first oxide layer;
b. causing a first oxidant to strip at least a portion of the patterned photoresist, and to form a second oxide layer on the portions of the substrate exposed by the etching step; and
c. causing a second etchant to contact the device precursor under conditions effective to selectively remove at least a portion of the second oxide layer relative to the first oxide layer.

15. The method of claim 14, wherein the first etchant comprises an aqueous acid.

16. The method of claim 15, wherein the first etchant comprises aqueous hydrofluoric acid.

17. The method of claim 15, wherein the etchant further comprises a salt of the aqueous acid.

18. The method of claim 14, wherein the first etchant comprises a combination of etchants.

19. The method of claim 18, wherein the combination of etchants is caused to etch one or more of the exposed portions of the first oxide layer simultaneously.

20. The method of claim 18, wherein the combination of etchants is caused to etch one or more of the exposed portions of the first oxide layer in succession.

21. The method of claim 18, wherein the combination of etchants is caused to etch one or more of the exposed portions of the first oxide layer in an overlapping fashion.

22. The method of claim 14, wherein the first oxidant comprises a combination of oxidants.

23. The method of claim 22, wherein the combination of oxidants contact the substrate simultaneously.

24. The method of claim 22, wherein the combination of oxidants is caused to contact the substrate in succession.

25. The method of claim 22, wherein the combination of oxidants is caused to contact the substrate in an overlapping fashion.

26. The method of claim 14, wherein the oxidant comprises SPM chemistry, APM chemistry, ozone gas, ozonated water, or a combination of these.

27. The method of claim 14, wherein the second etchant removes substantially all of the second oxide layer.

28. The method of claim 14, wherein the second etchant comprises dilute, aqueous hydrofluoric acid.

29. The method of claim 28, wherein the second etchant comprises an aqueous solution of less than 5 weight percent hydrofluoric acid.

30. The method of claim 29, wherein the second etchant comprises an aqueous solution of less than 1 weight percent hydrofluoric acid.

31. The method of claim 30, wherein the second etchant comprises an aqueous solution of from about 0.01 weight percent to about 3 weight percent hydrofluoric acid.

32. The method of claim 31, wherein the second etchant comprises an aqueous solution of from about 0.1 weight percent to about 1 weight percent hydrofluoric acid.

33. A method of treating an in-process microelectronic device precursor, wherein the precursor comprises a substrate, a first oxide layer over at least a portion of the substrate and a patterned photoresist over the first oxide layer and exposing one or more portions of the first oxide layer, comprising the steps of
a. causing a first etchant comprising aqueous HF and a buffering amount of a fluoride salt to etch one or more of the exposed portions of the first oxide layer to expose one or more portions of the substrate;
b. causing a first oxidant comprising ozone to strip at least a portion of the patterned photoresist, and to form a second oxide layer on the portions of the substrate exposed by the etching step; and
c. causing a second etchant comprising HF to contact the device precursor under conditions effective to selectively remove at least a portion of the second oxide layer relative to the first oxide layer.

34. A method of treating an in-process microelectronic device precursor, wherein the precursor comprises a substrate, a first oxide layer over at least a portion of the substrate and a patterned photoresist over the first oxide layer and exposing one or more portions of the first oxide layer, comprising the steps of
a. causing a first etchant to etch one or more of the exposed portions of the first oxide layer to expose one or more portions of the substrate;
b. causing a first oxidant to strip at least a portion of the patterned photoresist, and to form a second oxide layer on the portions of the substrate exposed by the etching step;
c. causing a second etchant to contact the device precursor under conditions effective to selectively remove at least a portion of the second oxide layer relative to the first oxide layer; and
d. causing a second oxidant to contact the device precursor under conditions effective to cause a third oxide layer to form on the device precursor.

35. The method of claim 34, wherein the third oxide layer is substantially devoid of metallic impurities.

36. The method of claim 34, wherein the second oxidant comprises ozone, ozonated water, deionized water, or a combination of these.

37. The method of claim 34, wherein the second oxidant comprises ozone gas co-introduced with deionized water.

38. The method of claim 34, wherein at least steps (a) and (b) are carried out within a single process chamber.

39. The method of claim 38, wherein at least steps (a), (b) and (c) are carried out within a single process chamber.

40. The method of claim 39, wherein at least steps (a), (b), (c) and (d) are carried out within a single process chamber.

41. The method of claim 34, wherein at least steps (b) and (c) are carried out within a single process chamber.

42. The method of claim 34, wherein at least steps (c) and (d) are carried out within a single process chamber.

43. The method of claim 34, wherein at least steps (b)(c) and (d) are carried out within a single process chamber.

44. A method of treating an in-process microelectronic device precursor, wherein the precursor comprises a substrate, a first oxide layer over at least a portion of the substrate and a patterned photoresist over the first oxide layer and exposing one or more portions of the first oxide layer, comprising the steps of
a. causing a first etchant comprising aqueous HF and a buffering amount of a fluoride salt to etch one or more of the exposed portions of the first oxide layer to expose one or more portions of the substrate;
b. causing a first oxidant comprising ozone to strip at least a portion of the patterned photoresist, and to form a second oxide layer on the portions of the substrate exposed by the etching step;
c. causing a second etchant comprising HF to contact the device precursor under conditions effective to selectively remove at least a portion of the second oxide layer relative to the first oxide layer; and
d. causing a second oxidant comprising ozone to contact the device precursor under conditions effective to cause a third oxide layer to form on the device precursor.
